(19) United States
(12) Patent Application Publication
(10) Pub. No.: US 2017/0077134 A1
(43) Pub. Date: Mar. 16, 2017

(54) SEMICONDUCTOR MEMORY DEVICE AND MANUFACTURING METHOD THEREOF

(71) Applicant: Kabushiki Kaisha Toshiba, Minato-ku (JP)

(72) Inventor: Shinya TAGUCHI, Yokkaichi (JP)

(73) Assignee: Kabushiki Kaisha Toshiba, Minato-ku (JP)

(21) Appl. No.: 15/071,421

(22) Filed: Mar. 16, 2016

Related U.S. Application Data
(60) Provisional application No. 62/216,586, filed on Sep. 10, 2015.

(51) Int. Cl. H01L 27/115; H01L 23/532; H01L 21/768; H01L 21/02; H01L 21/311

(52) U.S. Cl. CPC H01L 27/11582; H01L 21/022; H01L 21/31111; H01L 21/76802; H01L 21/76877; H01L 23/53295

(57) ABSTRACT

A semiconductor memory device according to an embodiment includes a laminated body. The laminated body is disposed above a semiconductor substrate. The laminated body includes a plurality of conductive layers and an interlayer insulating film. The interlayer insulating film is disposed between the plurality of conductive layers. A peripheral area of a semiconductor layer is surrounded by the laminated body. The semiconductor layer extends with a first direction as a longitudinal direction. A memory gate insulating film is disposed between the semiconductor layer and the laminated body. The memory gate insulating film includes a charge accumulation film. At least one of the interlayer insulating films disposed between the plurality of conductive layers include a first film and a second film. The first film has a first composition. The second film has a second composition different from the first composition.

### CROSS REFERENCE TO RELATED APPLICATIONS

This application is based on and claims the benefit of priority from prior U.S. Provisional Patent Application No. 62/216,586, filed on Sep. 10, 2015, the entire contents of which are incorporated herein by reference.

### BACKGROUND

Field

Embodiments described herein relate generally to a semiconductor memory device and a method of manufacturing thereof.

Description of the Related Art

As one of a semiconductor memory device, there has been provided a flash memory. In particular, since its inexpensiveness and large capacity, a NAND flash memory has been generally widely used. Up to the present, many techniques to further increase the capacity of this NAND flash memory have been proposed. One of the techniques is a structure of three-dimensionally disposing memory cells. In such three-dimensional semiconductor memory device, the memory cells are disposed in a laminating direction. Conductive layers extend from the respective memory cells, which are disposed in the laminating direction. Such conductive layers are electrically separated by interlayer insulating films in the laminating direction.

With such three-dimensional semiconductor memory device, as the thickness of the laminated body increases, an influence brought by the stress caused by the thickness cannot be ignored.

### BRIEF DESCRIPTION OF THE DRAWINGS

FIG. 1 is a function block diagram of a semiconductor memory device according to a first embodiment;

FIG. 2 is a schematic perspective view illustrating a configuration of a part of a memory cell array of the semiconductor memory device according to the first embodiment;

FIG. 3 is a schematic diagram illustrating a schematic configuration of a memory cell MC of the semiconductor memory device according to the first embodiment;

FIG. 4 is an equivalent circuit diagram of a memory unit MU of the semiconductor memory device according to the first embodiment;

FIG. 5 is a plan view describing detailed configurations of a memory area MR and a stepped wiring area CR of the semiconductor memory device according to the first embodiment;

FIG. 6 is a cross-sectional view describing detailed configurations of the memory area MR and the stepped wiring area CR of the semiconductor memory device according to the first embodiment;

FIG. 7 is a schematic diagram describing structures of interlayer insulating films 112 and 113 in the semiconductor memory device according to the first embodiment;

FIG. 7 is a cross-sectional view describing the structures of interlayer insulating films 112 and 113 according to the first embodiment;

FIG. 8 is a graph illustrating a relationship between internal stress of an interlayer insulating films made of a single material and the etching rate of the interlayer insulating film;

FIG. 9 is a graph illustrating a relationship between the internal stress of the interlayer insulating films and a collapse rate of a laminated structure including the interlayer insulating films;

FIG. 10A and FIG. 10B illustrate a modification of the first embodiment;

FIG. 11A to FIG. 11G are process drawings illustrating manufacturing processes of the semiconductor memory device according to the first embodiment;

FIG. 12 is a timing chart describing a method for manufacturing the three-layered structure (FIG. 7) with the interlayer insulating films 112 and 113;

FIG. 13 illustrates the modification of the first embodiment; and

FIG. 14 is a cross-sectional view describing the structures of the interlayer insulating films 112 and 113 according to the second embodiment.

### DETAILED DESCRIPTION

According to one embodiment, a semiconductor memory device includes a laminated body. The laminated body is disposed above a semiconductor substrate. The laminated body includes a plurality of conductive layers and an interlayer insulating film. The interlayer insulating layer is disposed between the plurality of conductive layers. A peripheral area of a semiconductor layer is surrounded by the laminated body. The semiconductor layer extends with a first direction as a longitudinal direction. A memory gate insulating film is disposed between the semiconductor layer and the laminated body. The memory gate insulating film includes a charge accumulation film. At least one of the interlayer insulating films disposed between the plurality of conductive layers include a first film and a second film. The first film has a first composition. The second film has a second composition different from the first composition.

The following describes non-volatile semiconductor memory devices according to embodiments with reference to the accompanying drawings. Here, these embodiments are only examples. For example, the semiconductor memory device described below has a structure where a memory string extends in a straight line in the vertical direction with respect to a substrate. The similar structure is also applicable to the structure having a U shape where a memory string is folded back to the opposite side in the middle. The respective drawings of the non-volatile semiconductor memory devices used in the following embodiments are schematically illustrated. The thickness, the width, the ratio, and a similar parameter of the layer are not necessarily identical to actual parameters.

The following embodiments relate to a non-volatile semiconductor memory device in a structure where a plurality of metal-oxide-nitride-oxide-semiconductor (MONOS) type memory cells (transistors) is disposed in a height direction. The MONOS type memory cell includes: a semiconductor film disposed in a columnar shape vertical to the substrate as a channel and a gate electrode film disposed on the side surface of the semiconductor film via a charge accumulation layer. However, a similar structure is applicable to another type, for example, a semiconductor-oxide-nitride-oxide-semiconductor (SONOS) type memory cell, a metal-aluminum oxide-nitride-oxide-semiconductor (MANOS) type memory cell, a memory cell that uses hafnium oxide (HfOₓ) or tantalum oxide (TaOₓ) as an insulating layer, or a floating-gate type memory cell.

### First Embodiment

First, the following describes an overall structure of a semiconductor memory device according to the first embodiment.

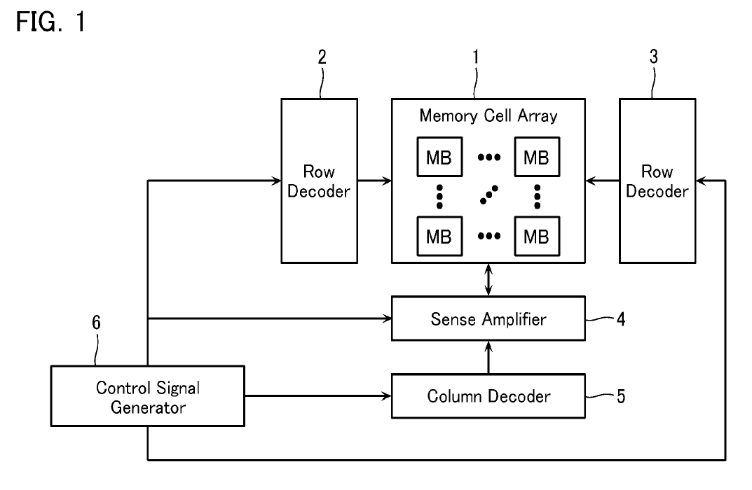

FIG. 1 is a function block diagram of a semiconductor memory device according to the first embodiment. This semiconductor memory device includes a memory cell array 1, row decoders 2 and 3, a sense amplifier 4, a column decoder 5, and a control signal generator 6.

The memory cell array 1 includes a plurality of memory blocks MB. The memory blocks MB each include a plurality of memory transistors. The memory transistors are a plurality of memory cells MC that are three-dimensionally disposed. The memory block MB is the minimum unit of data erasure operation.

The row decoders 2 and 3 decode retrieved block address signals or similar signals to control a writing operation and a reading operation of data in the memory cell array 1. The sense amplifier 4 detects electric signals flowing through a bit line during the reading operation and amplifies the electric signals. The column decoder 5 decodes column address signals to control the sense amplifier 4. The control signal generator 6 steps up a reference voltage to generate a high voltage used for the writing operation and the erasure operation. Besides, the control signal generator 6 generates control signals to control the row decoders 2 and 3, the sense amplifier 4, and the column decoder 5.

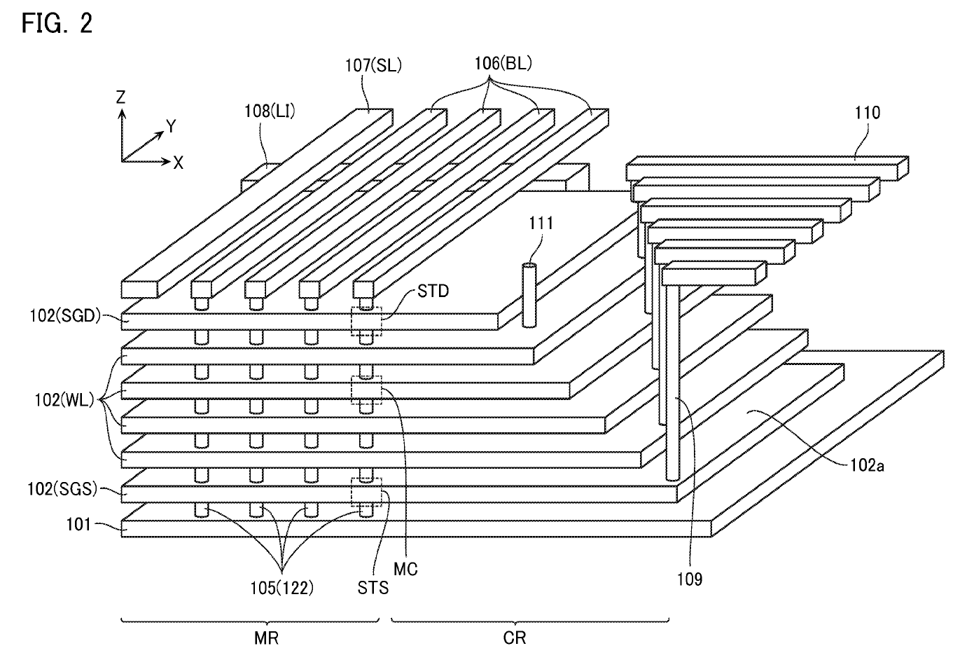

Next, the following describes the schematic structure of the memory cell array 1 according to the embodiment with reference to FIG. 2. FIG. 2 is a schematic perspective view illustrating the structure of a part of the memory cell array. FIG. 2 omits illustrations of a part of structures for simplifying the description. For simplifying the illustration, the numbers of respective wirings also differ from those of other drawings.

As illustrated in FIG. 2, the memory cell array 1 according to the first embodiment includes a substrate 101 and a plurality of conductive layers 102. The conductive layers 102 are laminated above the substrate 101 in a Z direction. The memory cell array 1 has a plurality of memory shafts 105 extending in the Z direction. As illustrated in FIG. 2, the intersection portions of the conductive layers 102 and the memory shafts 105 function as a source side select gate transistor STS, the memory cell MC, or a drain side select gate transistor STD. The conductive layer 102 is a conductive layer made of, for example, tungsten (W) and polysilicon. The conductive layer 102 functions as a word line WL, a source side select gate line SGS, and a drain side select gate line SGD.

As illustrated in FIG. 2, the plurality of conductive layers 102 include wiring parts, which are formed into a stepped pattern, on the end portions in the X direction. The following designates an area at which the memory cell MC or a similar component is disposed as a memory area MR. A part where the conductive layers 102 are formed into the stepped pattern by extracting the conductive layers 102 from this memory area MR is referred to as a stepped wiring area CR.

The conductive layers 102 in the stepped wiring area CR includes contact portions 102a. The contact portion 102a does not face the lower surface of the conductive layer 102, which is positioned on the upper layer of the contact portion 102a. The conductive layer 102 is connected to a contact plug 109 at this contact portion 102a. A wiring 110 is disposed at the upper end of the contact plug 109. The contact plug 109 and the wiring 110 are conductive layers made of, for example, tungsten.

As illustrated in FIG. 2, the memory cell array 1 according to the first embodiment includes a support pillar 111. The support pillar 111 is disposed so as to have a longitudinal direction in a laminating direction of a laminated body formed of the plurality of conductive layers 102 and the interlayer insulating layers between the conductive layers 102. This support pillar 111 is formed to maintain the posture of the laminated body during the manufacturing process for this laminated body. The conductive layers 102 can be formed by the following processes as described later. The interlayer insulating layers and sacrificial layers are laminated. Then, the sacrificial layers are removed by wet etching or a similar method. Afterward, the conductive films are embedded into voids formed by removing the sacrificial layers. When performing such processes, to prevent the interlayer insulating layer from collapsing, the above-described support pillar 111 is disposed. FIG. 2 representatively illustrates only the one support pillar 111. However, the actual device can include more of the support pillars 111.

As illustrated in FIG. 2, the memory cell array 1 according to the first embodiment includes a conductive layer 108. The conductive layer 108 opposes the side surfaces of the plurality of conductive layers 102 in the Y direction and extends in the X direction. The lower surface of the conductive layer 108 is in contact with the substrate 101. The conductive layer 108 is a conductive layer made of, for example, tungsten (W). The conductive layer 108 functions as a source contact LI.

The material of the conductive layer 102, as well as the above-described tungsten (W), is possibly configured of a conductive layer such as WN, Al, Ti, V, Cr, Mn, Fe, Co, Ni, Cu, TiN, WSiₓ, TaSiₓ, PdSiₓ, ErSiₓ, YSiₓ, PtSiₓ, HfSiₓ, NiSiₓ, CoSiₓ, TiSiₓ, VSiₓ, CrSiₓ, MnSiₓ, and FeSiₓ.

As illustrated in FIG. 2, the memory cell array 1 according to the first embodiment includes a plurality of conductive layers 106 and a conductive layer 107. The plurality of conductive layers 106 and the conductive layer 107 are disposed above the plurality of conductive layers 102 and memory shafts 105. The plurality of conductive layers 106 are disposed in the X direction. The plurality of conductive layers 106 and the conductive layer 107 extend in the Y direction. The memory shafts 105 are each connected to the lower surfaces of the conductive layers 106. The conductive layer 106 is, for example, configured of the conductive layer such as tungsten (W) and functions as a bit line BL. The conductive layer 108 is connected to the lower surfaces of the conductive layers 107. The conductive layer 107 is, for example, configured of the conductive layer such as tungsten (W) and functions as a source line SL.

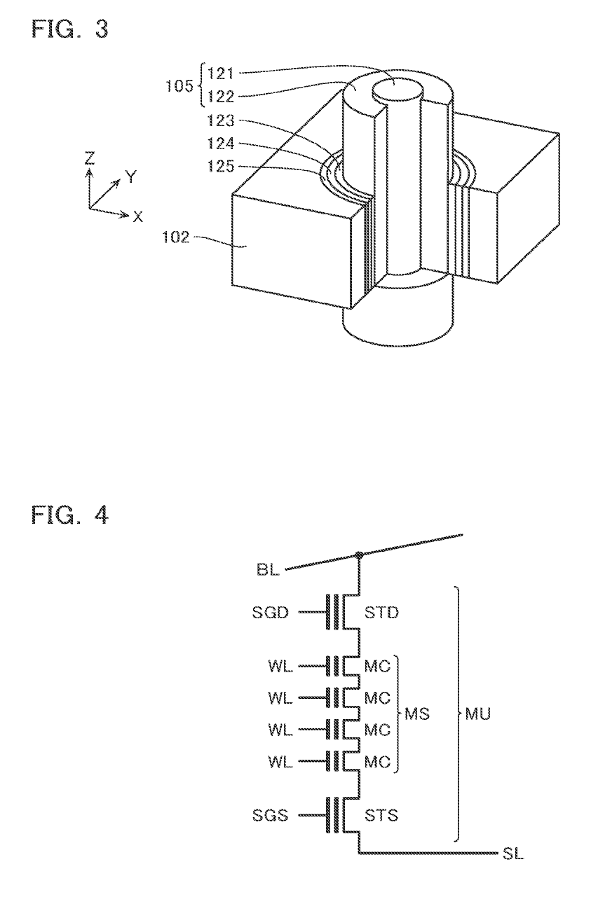

Next, with reference to FIG. 3, the following describes the schematic structure of the memory cell MC according to the first embodiment. FIG. 3 is a schematic perspective view illustrating the structure of the memory cell MC. FIG. 3 illustrates the structure of the memory cell MC. Note that the source side select gate transistor STS and the drain side select gate transistor STD may also be configured similar to the memory cell MC. FIG. 3 omits a part of the structure.

As illustrated in FIG. 3, the memory cell MC is disposed at a portion where the conductive layer 102 intersects with the memory shaft 105. The memory shaft 105 includes a core insulating layer 121 and a columnar semiconductor layer 122. The semiconductor layer 122 covers the sidewall of the core insulating layer 121. Moreover, between the semiconductor layer 122 and the conductive layer 102, a memory gate insulating film is disposed. The memory gate insulating film includes a tunnel insulating layer 123, a charge accumulation layer 124, and a block insulating layer 125. The core insulating layer 121 is configured of, for example, an insulating layer such as silicon oxide (SiO₂). The semiconductor layer 122 is constituted of, for example, a semiconductor layer such as polysilicon. The semiconductor layer 122 functions as a channel for the memory cell MC, the source side select gate transistor STS, and the drain side select gate transistor STD. The tunnel insulating layer 123 is configured of, for example, an insulating layer such as silicon oxide (SiO₂). The charge accumulation layer 124 is configured of, for example, an insulating layer such as silicon nitride (SiN) that can accumulate charges. The block insulating layer 125 is configured of, for example, an insulating layer such as silicon oxide (SiO₂).

The material of the semiconductor layer 122, in addition to the above-described polysilicon, for example, is possibly configured of a semiconductor such as SiGe, SiC, Ge, and C. Silicide may be formed on contact surfaces between the semiconductor layers 122 and the substrate 101 and between the semiconductor layers 122 and the conductive layer 106. As such silicide, for example, it is considered that Sc, Ti, VCr, Mn, Fe, Co, Ni, Cu, Zn, Rh, Pd, Ag, Cd, In, Sn, La, Hf, Ta, W, Re, Os, Ir, Pt, and Au are used. Further, to the silicide thus formed, Sc, Ti, VCr, Mn, Fe, Co, Ni, Cu, Y, Zr, Nb, Mo, Tc, Ru, Rh, Pd, Ag, Cd, In, Sn, La, Hf, Ta, W, Re, Os, Ir, Pt, Au, or a similar material may be added.

The tunnel insulating layer 123 and the block insulating layer 125 are possibly formed of, for example, a material such as oxide and oxynitride, in addition to the above-described silicon oxide (SiO₂). The oxide configuring the tunnel insulating layer 123 and the block insulating layer 125 is possibly SiO₂, Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, AlSiO, or a similar material. The oxide configuring the tunnel insulating layer 123 and the block insulating layer 125 may also be AB₂O₄. Note that A and B described here are identical or different elements and one of elements among Al, Sc, Ti, V, Cr, Mn, Fe, Co, Ni, Cu, Zn, Ga, and Ge. For example, AB₂O₄ is Fe₃O₄, FeAl₂O₄, Mn₁₊ₓAl₂₋ₓO_{4+y}, CO₁₊ₓAl₂₋ₓO_{4+y}, or MnOₓ.

The oxide configuring the tunnel insulating layer 123 and the block insulating layer 125 may be ABO₃. Note that A and B described here are identical or different elements and one of elements among Al, La, Hf, Ta, W, Re, Os, Ir, Pt, Au, Hg, Tl, Pb, Bi, Ce, Pr, Nd, Pm, Sm, Eu, Gd, Tb, Dy, Ho, Er, Tm, Yb, Lu, Sc, Ti, V, Cr, Mn, Fe, Co, Ni, Cu, Zn, Ga, Ge, Y, Zr, Nb, Mo, Tc, Ru, Rh, Pd, Ag, Cd, In, and Sn. For example, ABO₃ is LaAlO₃, SrHfO₃, SrZrO₃, or SrTiO₃.

The oxynitride configuring the tunnel insulating layer 123 and the block insulating layer 125 is possibly, for example, SiON, AlON, YON, LaON, GdON, CeON, TaON, Hf ON, ZrON, TiON, LaAlON, SrHfON, SrZrON, SrTiON, HfSiON, HfAlON, ZrSiON, ZrAlON, and AlSiON.

The oxynitride configuring the tunnel insulating layer 123 and the block insulating layer 125 may be a material configured by replacing some of oxygen elements of the respective materials described above as an oxide configuring the tunnel insulating layer 123 and the block insulating layer 125 with a nitrogen element.

As the material for the tunnel insulating layer 123 and the block insulating layer 125, SiO₂, SiN, Si₃N₄, Al₂O₃, SiON, HfO₂, HfSiON, Ta₂O₅, TiO₂, or SrTiO₃ is preferable.

In particular, an Si-based insulating film such as SiO₂, SiN, and SiON includes an insulating film whose respective concentrations of the oxygen element and the nitrogen element are 1×10¹⁸ atoms/cm³ or more. Note that a barrier height of the plurality of insulating layers differ from one another.

The tunnel insulating layer 123 and the block insulating layer 125 may include a material including impurity atoms that form a defect level or semiconductor/metal dots (the quantum dots).

The connection of the memory cell MC and the select gate transistors STD and STS with the above-described structure in series configures a memory unit MU as illustrated in FIG. 4. That is, the memory unit MU includes a memory string MS, the source side select gate transistor STS, and the drain side select gate transistor STD. The memory string MS is formed of the plurality of memory cells MC connected in series. The source side select gate transistor STS and the drain side select gate transistor STD are connected to both ends of the memory string MS. Some of the plurality of memory cells MC in the memory string MS can be dummy cells not used for data storage. The number of dummy cells can be set to any given number.

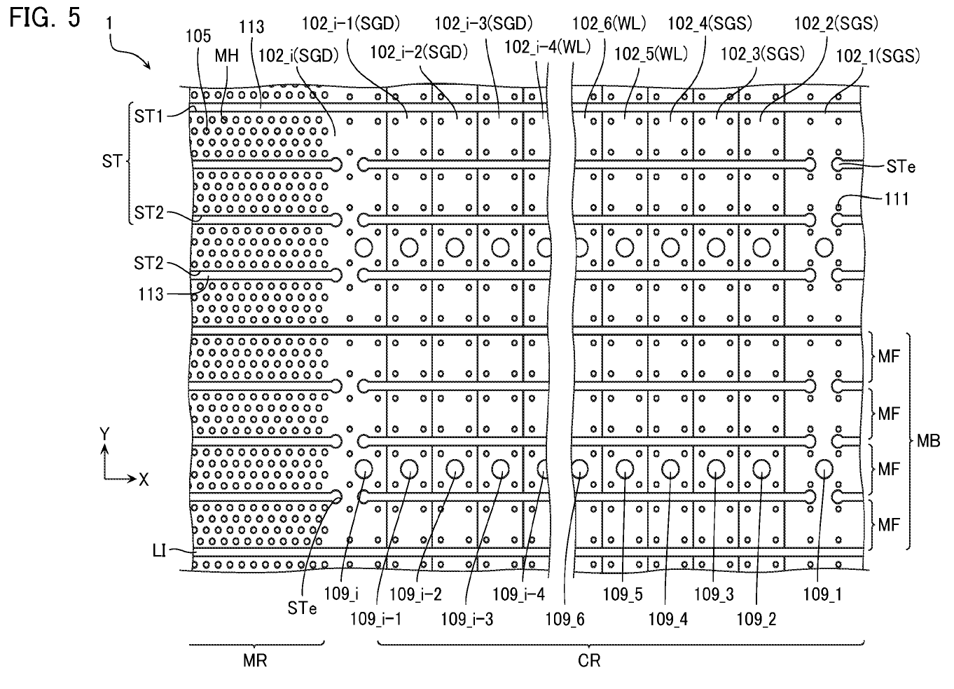

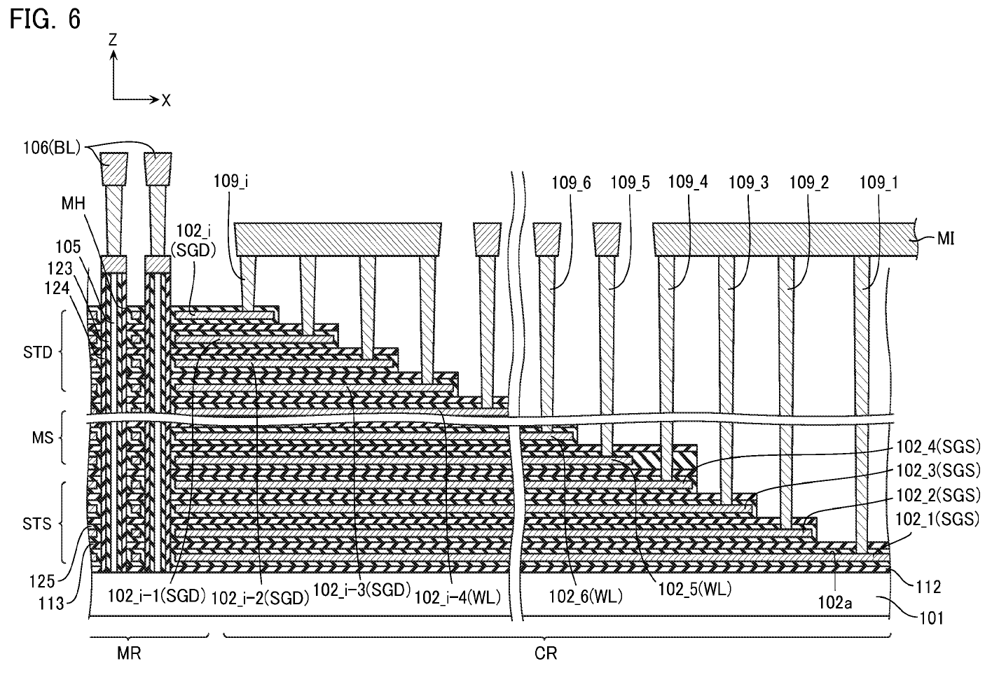

Next, with reference to FIG. 5 and FIG. 6, the following describes details of the structure of the memory area MR and the stepped wiring area CR of the semiconductor memory device according to the first embodiment. FIG. 5 is a plan view illustrating the structures of the memory area MR and the stepped wiring area CR. FIG. 6 is a cross-sectional view of the memory area MR and the stepped wiring area CR along the X-Z plane in FIG. 5. FIG. 5 and FIG. 6 differ in the numbers of word lines WL and the select gate lines SGD and SGS from those of the schematic diagram in FIG. 2.

As illustrated in FIG. 5, the memory cell array 1 according to the first embodiment includes the memory area MR and the stepped wiring area CR. The memory unit MU is formed at the memory area MR. The stepped wiring area CR extends from the memory area MR.

As illustrated in FIG. 6, in the memory area MR, a plurality of (i pieces) of the conductive layers 102 (102_1 to 102_i) are laminated on the substrate 101 sandwiching the interlayer insulating films 112 and 113. As described later, the interlayer insulating films 112 and 113 have a structure where a plurality of kinds of materials with different compositions are laminated.

A large number of memory holes MH are formed in the memory area MR so as to penetrate the laminated body of these conductive layers 102 and interlayer insulating films 112 and 113. In this memory hole MH, the above-described memory shaft 105 is formed via the tunnel insulating layer 123 and the charge accumulation layer 124 (see FIG. 6). That is, the memory shaft 105 is formed such that the peripheral area of the memory shaft 105 is surrounded by the laminated body of the conductive layer 102 and the interlayer insulating films 112 and 113.

As illustrated in FIG. 6, the block insulating layers 125 are formed not the inside of the memory holes MH but so as to cover the peripheral areas of the conductive layers 102_1 to 102_i. The upper end of the memory shaft 105 is connected to the above-described conductive layer 106 (the bit line BL) via a contact wiring or a similar wiring.

In the example illustrated in FIG. 5, the memory holes MH are disposed in a houndstooth pattern in the X-Y plane. The disposition of the memory holes MH in the X-Y direction can be appropriately adjusted into a triangular disposition, a square disposition, or a similar disposition.

As illustrated in FIG. 5, a large number of the above-described support pillars 111 are formed at the stepped wiring area CR. Contact plugs 109 (109_1 to 109_i) are connected to the exposed portions of the respective conductive layers 102 configuring the stepped wiring area CR. The upper ends of the contact plug 109 are connected to upper layer wirings M1. Through such upper layer wirings M1 and wiring layers (not illustrated), the contact plug 109 is connected to an external circuit. This upper layer wiring M1 functions as the wiring 110 in FIG. 2.

As illustrated in FIG. 6, with the first embodiment, the conductive layers 102_1 to 102_4 function as control gate electrodes for the source side select gate line SGS and the source side select gate transistor STS. That is, in the structure illustrated in FIG. 6, the four source side select gate lines SGS are connected to the one source side select gate transistor STS.

The conductive layers 102_5 to 102_i−4 function as control gates for the word lines WL and the memory cells MC. That is, in the structure illustrated in FIG. 6, the one memory string MS includes (i−8) pieces of the memory cells MC. (i−8) pieces of the word lines WL are connected to the memory cells MC.

The conductive layers 102_i−3 to 102_i function as control gate electrodes for the drain side select gate line SGD and the drain side select gate transistor STD. That is, in the structure illustrated in FIG. 6, the four drain side select gate lines SGD are connected to the one drain side select gate transistor STD.

The stepped wiring area CR has a structure of forming the above-described conductive layers 102 and interlayer insulating films 113 in a stepped pattern. As a result of formed in the stepped pattern, the conductive layers 102 each include contact formation area 102a, which are not covered with the conductive layers on their upper layers. The contact formation area 102a can be connected to the contact plug 109 on this exposed part. The upper end of the contact plug 109 is connected to the upper layer wiring M1.

As illustrated in FIG. 5, a large number of slits ST (ST1 and ST2) with the longitudinal direction in the X direction are formed at the memory area MR and the stepped wiring area CR. An interlayer insulating film 113 is embedded or the above-described source contact LI is embedded into the slit ST via the isolation insulating film. That is, by being embedded into the slit ST, the interlayer insulating film 113 has a role to electrically insulate and separate the interlayer insulating films 112 positioned at both sides. When forming the conductive layer 102, this slit ST is formed to remove the sacrificial film, which will be described later, by etching.

As illustrated in FIG. 5, the slit ST extends with the X direction as the longitudinal direction. Additionally, the slit ST is formed so as to separate the laminated body of the conductive layers 102 and the interlayer insulating films 112 and 113 from the surface to the bottom. Thus, the slit ST separates the conductive layers 102_2 to 102_i in the memory area MR and the stepped wiring area CR in the Y direction. The slits ST have two types of the slits ST1 and ST2. All the slits ST1 and ST2 are formed to extend from the surface of the conductive layer 102_i to the substrate 101. This slit ST1 divides the memory area MR and the stepped wiring area CR into the plurality of memory blocks MB. Furthermore, the slit ST2 divides the one memory block MB into a plurality of memory fingers MF.

The slit ST1 is a slit formed between the two memory blocks MB. The slit ST2 is a slit formed between the two memory fingers MF in the one memory block MB. The slit ST1 separates the two memory blocks MB up to the conductive layer 102_1, which is the lowermost layer. Meanwhile, the slit ST2 has a terminating end portion STe at any position in the stepped wiring area CR. In the example illustrated in FIG. 5, the terminating end portions STe are formed at the conductive layer 102_i, which is the uppermost layer, and at the conductive layer 102_1, which is the lowermost layer. The slits ST2 are continuously formed opposed to one another sandwiching the terminating end portion in the X direction. In view of this, the slit ST2 does not electrically separate the conductive layers 102 in the adjacent memory fingers MF. The adjacent memory fingers MF are electrically connected to one another at the parts of the terminating end portions STe (More specifically, at the position between the two terminating end portions STe disposed alongside in the X direction, the conductive layer 102 disposed at a first side, which is the Y direction viewed from the slit ST2, and the conductive layer 102 disposed at a second side, which is the Y direction viewed from the slit ST2, are electrically connected). Thus, the reason the slits ST2 have the terminating end portions STe is as follows. The plurality of memory fingers MF included in the one memory block MB are not electrically separated but remain to be connected to reduce the number of required contact plugs. Obviously, the positions where the terminating end portions STe are formed are not limited to the example illustrated in the drawing. For example, the terminating end portion STe may be formed on the conductive layer 102_1, which is on the lowermost layer, only.

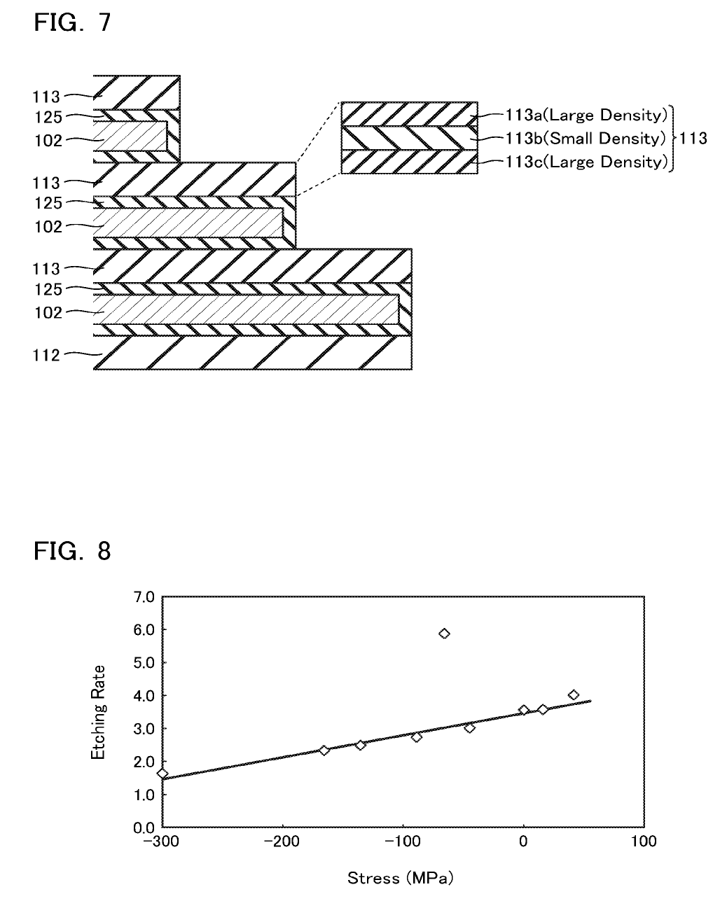

Next, with reference to FIG. 7, the following describes the structures of the interlayer insulating films 112 and 113.

As illustrated in FIG. 7, the interlayer insulating film 113 of the first embodiment includes two layers of first films 113a and 113c and a second film 113b. The films 113a to 113c are laminated in this order from the upper layer. The second film 113b is formed so as to be sandwiched between the two first films 113a and 113c from the upper and the lower.

As one example, all the first film 113a and 113c and the second film 113b in this embodiment can be formed of a plasma TEOS film using tetraethoxysilane gas (Si(OC₂H₅)₄: hereinafter referred to as “TEOS gas”) as raw material gas. Instead of the plasma TEOS, the films 113a to 113c may be formed with a plasma silane film using silane gas (SiH₄) as the raw material gas. However, in any cases, the second film 113b is designed as a film that has a different composition from the first films 113a and 113c.

For example, the second film 113b is designed as the film at a density smaller than the first films 113a and 113c. As described later, the film density can be changed by adjusting the flow rate of the TEOS gas by a CVD method, which is performed to deposit the films. As the film density decreases, the internal stress of these films decreases accordingly. Since the second film 113b has the small film density, compared with the first films 113a and 113c, the internal stress of the second film 113b is also small. Thus, the small internal stress of the second film 113b allows decreasing the internal stress compared with the case where the entire interlayer insulating film 113 is made of the identical material. This allows restraining a strain generated in the laminated structure.

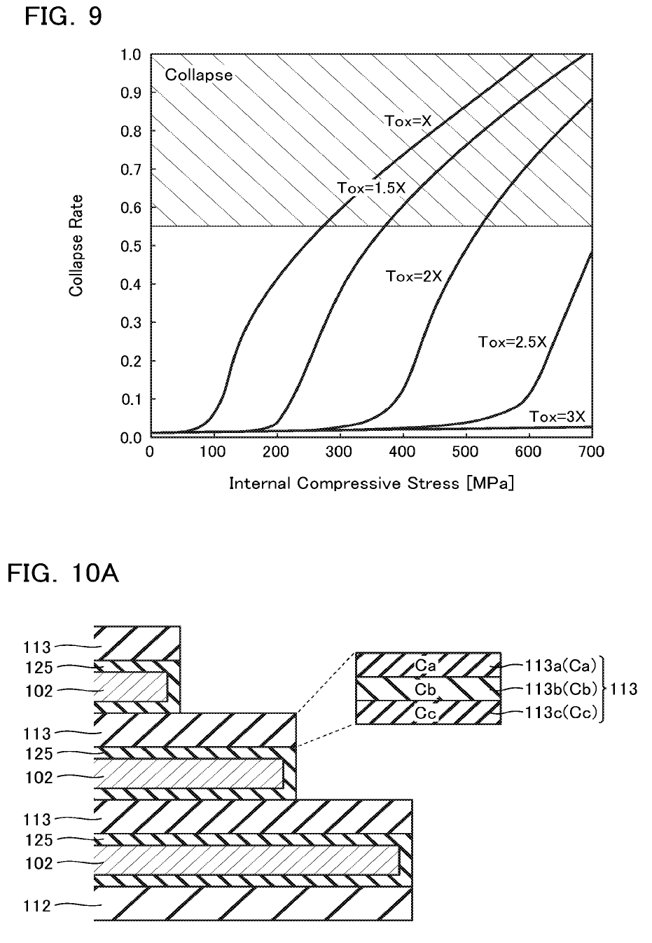

Designing the entire interlayer insulating film 113 to be the film of small film density allows further decreasing the internal stress. However, in this case, the wet etching resistance of the interlayer insulating film 113 deteriorates. FIG. 8 is a graph illustrating a relationship between the internal stress of the interlayer insulating film made of a single material and the etching rate of the interlayer insulating film. The vertical axis in FIG. 8 indicates the etching rate on a silicon oxide film under predetermined conditions. The vertical axis indicates that as the value increases, the etching is likely to occur. In view of this, simply decreasing the film density of the interlayer insulating film 113 to decrease the internal stress only deteriorates the wet etching resistance, resulting in reduction in the film thickness of the interlayer insulating film. Meanwhile, reducing the internal stress of the interlayer insulating film is indispensable to prevent the strain and collapse of the laminated structure and a deflection of the interlayer insulating film 113. FIG. 9 is a graph illustrating the relationship between the internal stress of the interlayer insulating films and the collapse rate of the laminated structure including the interlayer insulating films. As illustrated in FIG. 9, as the internal stress of the interlayer insulating film increases, the collapse rate increases. The degree of increase becomes remarkable as a film thickness Tox of the interlayer insulating film reduces.

In view of this, as described above, this embodiment employs the structure where the first films 113a and 113c sandwich the second film 113b. The film density of the first films 113a and 113c, which cover the second film 113b, is large. Therefore, although the internal stress is large, the wet etching resistance is high (the etching rate is low). This allows ensuring the wet etching resistance of the interlayer insulating film 113 while restraining the increase in internal stress. As illustrated in FIG. 9, reducing the internal stress allows decreasing the possibility of collapsing the laminated structure.

However, opposite from the above-described structure, it is also possible to increase the etching rate of the first films 113a and 113c compared with the second film 113b. Additionally, the internal stress of the first films 113a and 113c may be set smaller than the second film 113b. Setting the internal stress of the first films 113a and 113c smaller than the second film 113b appropriately adjusts the internal stress of the entire interlayer insulating film 113 and allows the offset of the internal stress of the conductive layer 102 in some cases. To be short, it is only necessary that the first films 113a and 113c and the second film 113b have different compositions from one another. The magnitude relationship between the internal stress and the etching rate can be appropriately determined according to the internal stress of the conductive layer 102 or a similar parameter.

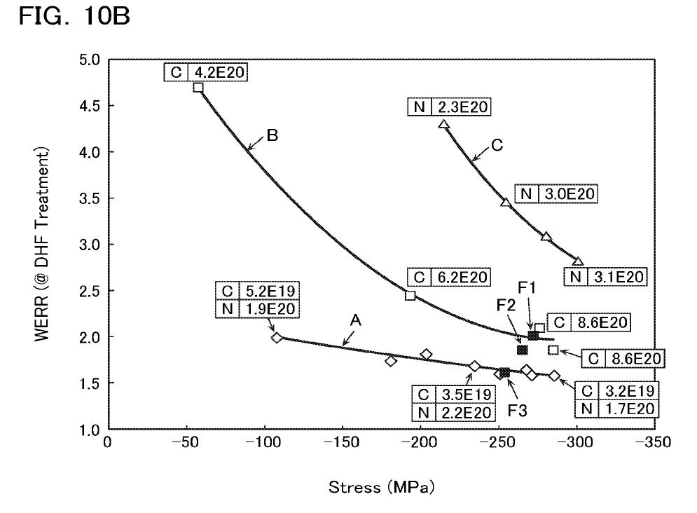

As illustrated in FIG. 10A, instead of differentiating the film density, it is also possible to differentiate concentrations Ca, Cb, and Cc of carbon (C) contained in the films 113a to 113c between the first films 113a and 113c and the second film 113b (Cb # Ca and Cc). The concentration of the carbon can be changed by adjusting a TEOS gas flow rate, a flow rate of oxidant, a high-frequency output (RF) from a plasma CVD apparatus, or a similar parameter by the CVD method. Instead of the carbon, the concentration of nitrogen (N) in the films 113a to 113c can also be changed. The concentration of nitrogen can be changed by N₂O flow rate, the high-frequency output (RF) from the plasma CVD apparatus, or a similar parameter by the CVD method.

The graph in FIG. 10B illustrates the relationship between the internal stress and the etching rate of the interlayer insulating films of each of three kinds of interlayer insulating films A, B, and C with different compositions. Here, the interlayer insulating films A and B are plasma TEOS films while the interlayer insulating film C is the plasma silane film. The interlayer insulating films A and B differ in deposition conditions from one another.

As indicated as values in the plots in the graph, it is found that the change in the concentrations of the carbon/nitrogen changes the internal stress of the oxide film. The square plots in FIG. 10B indicate the case where the flow rate of the oxidant is changed to F1, F2, and then F3 in the film formation of the interlayer insulating film B (F1>F2>F3). As indicated by these square plots, if changing the flow rate of the oxidant, even if the internal stress is almost identical, the carbon concentrations significantly differ.

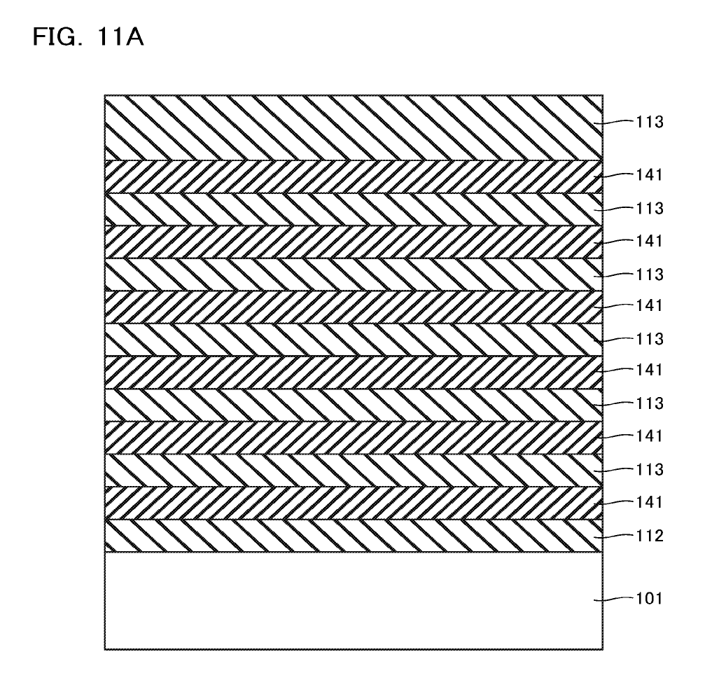

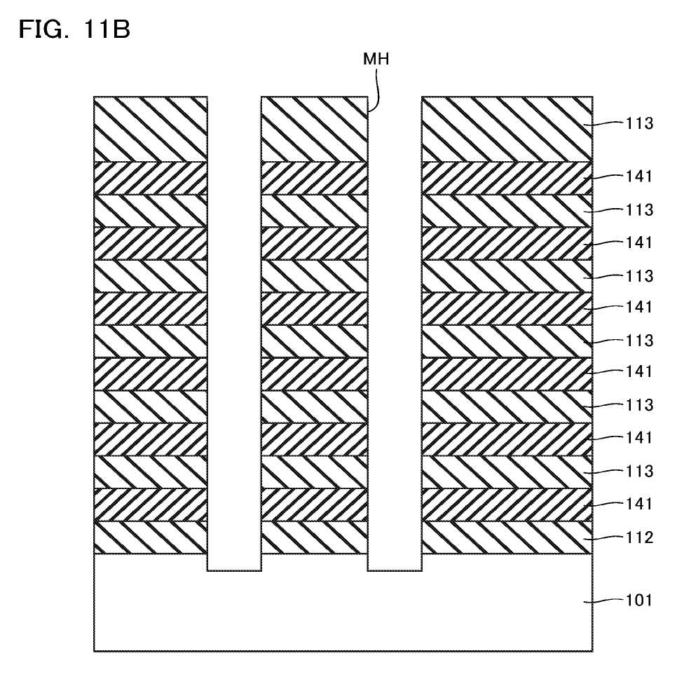

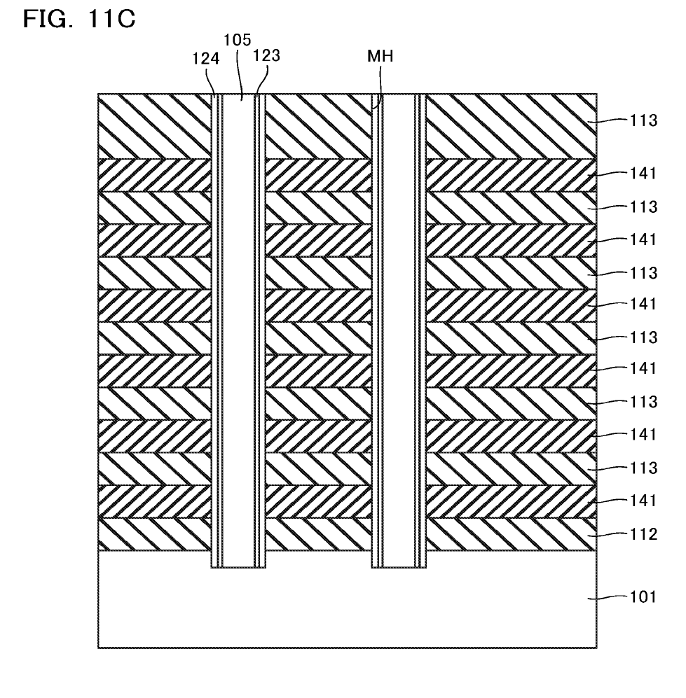

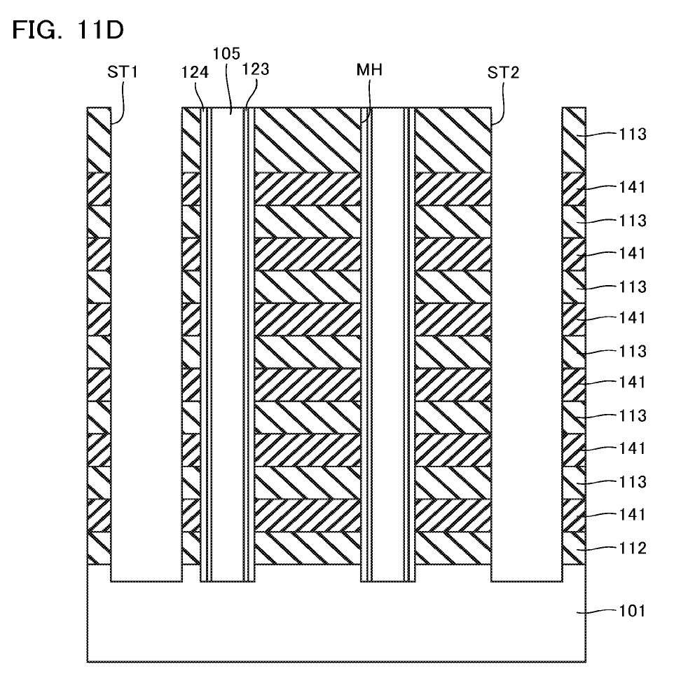

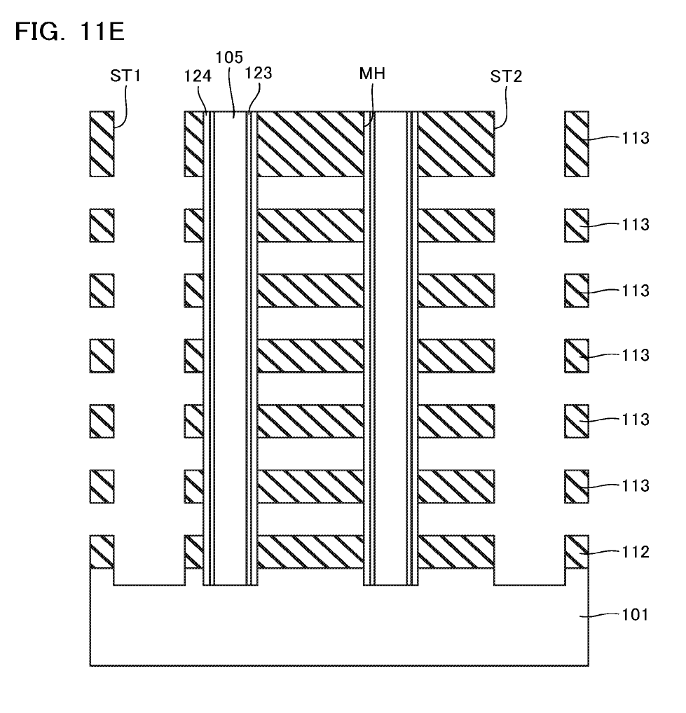

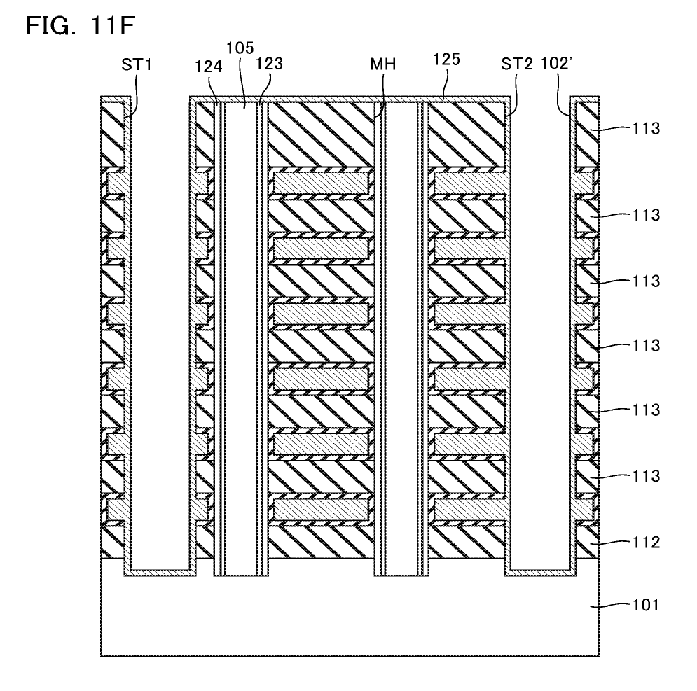

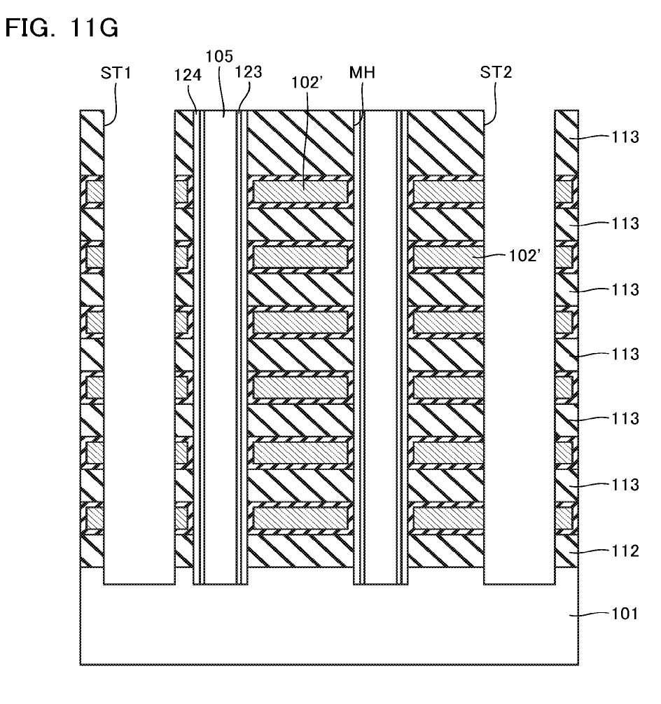

The following describes the manufacturing process of the laminated body of the conductive layers 102 and the interlayer insulating films according to the first embodiment with reference to FIG. 11A to FIG. 11G. As described later, the laminated body of the conductive layers 102 and the interlayer insulating films is formed as follows. First, the interlayer insulating films and the sacrificial films are laminated in alternation, and the sacrificial films are removed. After that, the conductive layers 102 are embedded into the voids from which the sacrificial films have been removed. In the laminated body of the conductive layers 102 and the interlayer insulating films 113, from an aspect of reduction in its resistivity, the conductive layer 102 is preferably formed of a metal film such as tungsten. However, it is not easy to form the memory hole MH, which penetrates the tungsten films and silicon oxide films, at a high density. In view of this, as described below, the laminated body of the conductive layers 102, which are formed of the metal films, and the interlayer insulating films 113 is formed as follows. The interlayer insulating films and the sacrificial films are laminated in alternation, and the sacrificial films are removed. After that, the conductive layers 102 are embedded into the voids from which the sacrificial films have been removed. The following describes the processes in detail with reference to FIG. 11A to 11F.

First, as illustrated in FIG. 11A, the interlayer insulating films 112 and 113 are laminated sandwiching a sacrificial layer 141 between them above the semiconductor substrate 101. When forming the interlayer insulating films 112 and 113 with silicon oxide film, the sacrificial layer 141 can be configured of silicon nitride film (SiN). Although FIGS. 11A to 11G omit the illustration of these interlayer insulating films 112 and 113, the interlayer insulating films 112 and 113 are deposited so as to have the three-layered structure (113a to 113c), which is as illustrated in FIG. 7 or FIG. 10A. The method for forming this three-layered structure will be described later.

Subsequently, as illustrated in FIG. 11B, the memory holes MH penetrating the interlayer insulating films 112 and 113 and sacrificial films 114 are formed. Next, as illustrated in FIG. 11C, the CVD method is performed to sequentially form the charge accumulation layers 124, the tunnel insulating layers 123, and the memory shafts 105 in the memory holes MH, thus forming the memory units MU.

As illustrated in FIG. 11D, after forming the memory shafts 105 or a similar member, RIE is performed to form the slits ST1 and ST2 penetrating the interlayer insulating films 112 and 113 and the sacrificial layers 141.

Next, as illustrated in FIG. 11E, by the wet etching using a hot phosphoric acid solution via the slits ST1 and ST2, the sacrificial films 141 are removed. As illustrated in FIG. 11F, conductive films 102′ comprised of tungsten are deposited to the voids left after removing the sacrificial films 141 by the CVD method. The deposited conductive films 102′ are deposited to project from the inner walls of the slits ST1 and ST2 to the centers of the slits. If such conductive films 102′, which project from the inner walls of the slits ST1 and ST2 to the center, are left, the conductive film 102′, which is opposed to the conductive film 102′ sandwiching the interlayer insulating layer in the laminating direction, shorts, failing to obtain the desired operation. Accordingly, as illustrated in FIG. 11G, the wet etching is further performed to etch-back the conductive film 102′. This prevents the conductive films 102′ adjacent in the laminating direction from shorting. The interlayer insulating films are embedded into the slits ST1 and ST2. Alternatively, the metal films, which will be the source contacts LI, are embedded into the slits ST1 and ST2 via the interlayer insulating films. This completes the structure illustrated in FIG. 2 to FIG. 6.

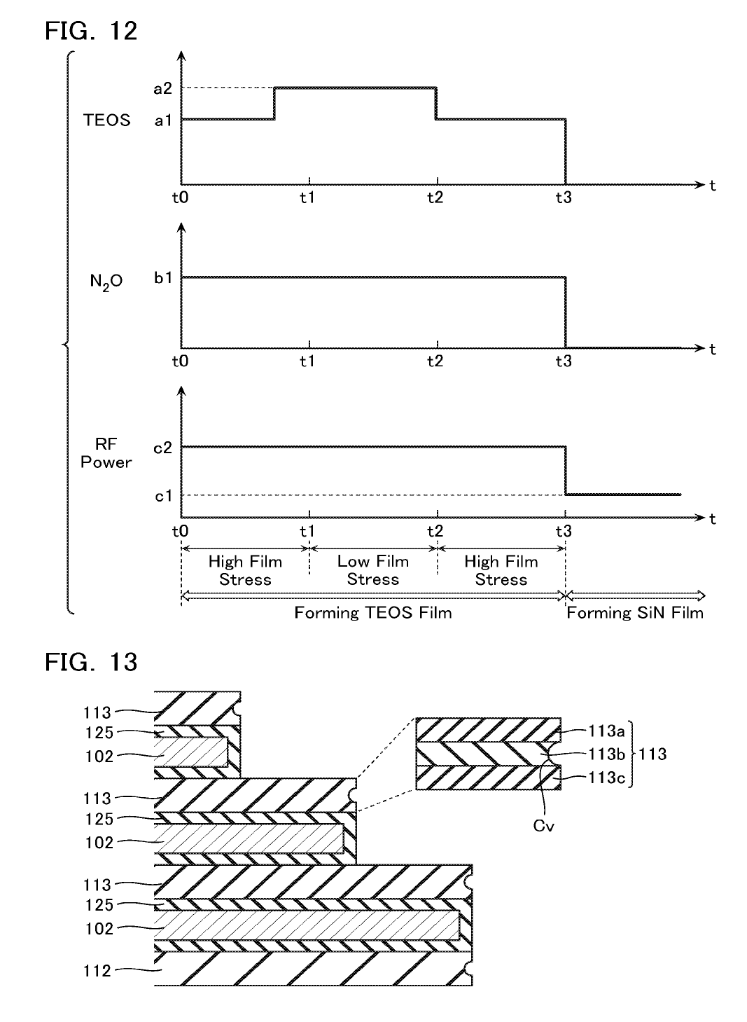

Next, the following describes a method for manufacturing the three-layered structure (FIG. 7) of the interlayer insulating films 112 and 113 with reference to FIG. 12.

FIG. 12 illustrates change in the flow rate of the TEOS gas, the oxygen (O₂) as the oxidant, the change in nitrous oxide (N₂O gas), and the change in the high-frequency output (RF) of the plasma CVD apparatus in the case where the three films 113a to 113c in the interlayer insulating film 113 are deposited in this order using the plasma CVD method. As illustrated in FIG. 12, to deposit the first film 113c, the second film 113b, and the first film 113a in this order from the substrate side, in the deposition phase (times t1 to t2) of the second film 113b, the flow rate of the TEOS gas is heightened (a flow rate a2). In the deposition phase (times t0 and t1 and t2 and t3) of the first films 113c and 113a, the flow rate of the TEOS gas is restrained low (a flow rate a1). The oxygen (O₂), N₂O, the flow rate of the gas, and the high-frequency output are designed to be constant between the times t0 to t3. This allows decreasing the film density of the second film 113b compared with the first films 113a and 113c. Obviously, the method illustrated in FIG. 12 is one example, and other methods are applicable. For example, while designing the flow rate of the TEOS gas constant, the high-frequency output and the flow rate of the oxidant are changed, ensuring changing the film density.

In the case where the interlayer insulating film 113 is formed into the three-layered structure, which is as illustrated in FIG. 7 and FIG. 10A, the second film 113b, which is sandwiched between the first films 113a and 113c, has a concave portion Cv on the end portion (the side surface) retreated compared with the end portions of the first films 113a and 113c (see FIG. 13). This occurs due to the following circumstances. The etching rate of the second film 113b is higher than the etching rate of the first films 113a and 113c. Therefore, for example, the etching for processing the interlayer insulating film 113 is likely to erode the end portion.

As described above, according to the semiconductor memory device of this first embodiment, the interlayer insulating film is formed of the laminated structure with the materials of different compositions. This allows effectively restraining the strain of the laminated structure.

### Second Embodiment

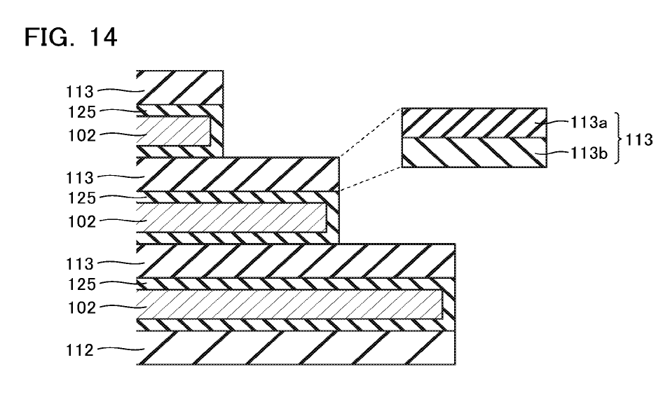

Next, the following describes a semiconductor memory device according to the second embodiment with reference to FIG. 14. This second embodiment differs from the first embodiment only in the structures of the interlayer insulating films 112 and 113.

This second embodiment includes the interlayer insulating film 113 formed of a two-layer structure, the one first film 113a and the one second film 113b. This respect differs from the first embodiment, which includes the interlayer insulating films 113 in the three-layered structure (FIG. 7 and FIG. 10A). Although the illustration is omitted, the same applies to the interlayer insulating film 112.

Similar to the first embodiment, the first film 113a and the second film 113b differ in the composition from one another. For example, the first films 113a and 113b may have different film densities. The film with small film density has the smaller internal stress compared with the film with high film density. The densities of contained carbon and nitrogen may differ.

In this second embodiment, the first films 113a do not sandwich the second film 113b from the top and lower surfaces of the second film 113b. Simply, only the one first film 113a is formed on the top surface of the second film 113b. This embodiment also allows reducing the internal stress by the combination of the first film 113a and the second film 113b.

### Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the interlayer insulating film 113 of the first embodiment has the following structure. The first films 113a and 113c whose film density is large and internal stress is large are present in the lowermost layer and the uppermost layer of the interlayer insulating film 113. The second film 113b whose film density is small and internal stress is small is sandwiched between the first films 113a and 113c. However, it is also possible that the plurality of three-layered structures, the first films/second films/first films, are repeatedly formed in one interlayer insulating film.

It is also possible that the plurality of two-layered structures, the first films/second films, are repeatedly configured in the one interlayer insulating film. In short, it is only necessary that the one interlayer insulating film includes at least one of the respective first film and second film. It is unnecessary that the all of the plurality of interlayer insulating films included in the laminated structure have the above-described three-layered structure or the two-layered structure. As long as at least the one interlayer insulating film has the above-described three-layered structure or two-layered structure, the structure is included in the scope of the invention.

What is claimed is:

1. A semiconductor memory device, comprising:
a semiconductor substrate;
a laminated body disposed above the semiconductor substrate, the laminated body including a plurality of conductive layers and an interlayer insulating film, the interlayer insulating film being disposed between the plurality of conductive layers;
a semiconductor layer whose peripheral area is surrounded by the laminated body, the semiconductor layer extending with a first direction as a longitudinal direction; and
a memory gate insulating film disposed between the semiconductor layer and the laminated body, the memory gate insulating film including a charge accumulation film, wherein
at least one of the interlayer insulating films disposed between the plurality of conductive layers include a first film and a second film, the first film having a first composition, the second film having a second composition different from the first composition.

2. The semiconductor memory device according to claim 1, wherein
the first film and the second film have different internal stresses.

3. The semiconductor memory device according to claim 1, wherein
the first film and the second film have different densities.

4. The semiconductor memory device according to claim 1, wherein
the first film contains carbon or nitrogen at a first concentration, and
the second film contains carbon or nitrogen at a second concentration different from the first concentration.

5. The semiconductor memory device according to claim 1, wherein
the interlayer insulating film includes the plurality of first films and the second film, the plurality of first films sandwiching the second film from upper and lower sides.

6. The semiconductor memory device according to claim 5, wherein
the first film is made of a material whose etching rate differs from the second film in an under a certain condition.

7. The semiconductor memory device according to claim 5, wherein
the second film has a concave portion on an end portion, the concave portion being retreated compared with positions of end portions of the first films.

8. The semiconductor memory device according to claim 5, wherein
the first film and the second film have different internal stresses.

9. The semiconductor memory device according to claim 5, wherein
the first film and the second film have different densities.

10. The semiconductor memory device according to claim 5, wherein
the first film contains carbon or nitrogen at a first concentration, and
the second film contains carbon or nitrogen at a second concentration different from the first concentration.

11. The semiconductor memory device according to claim 10, wherein
the first film and the second film have different internal stresses.

12. A method for manufacturing a semiconductor memory device, wherein
the semiconductor memory device includes a laminated body disposed above a semiconductor substrate, the laminated body including a plurality of conductive layers and an interlayer insulating film, the interlayer insulating film being disposed between the plurality of conductive layers, the method comprising:
laminating the interlayer insulating films and sacrificial films in alternation on the substrate;
removing the sacrificial film by etching; and
embedding a conductive film into a void, the void being generated by removal of the sacrificial film, wherein
each of the interlayer insulating films are formed by lamination of a first film and a second film in a laminating direction, the first film having a first composition, the second film having a second composition different from the first composition.

13. The manufacturing method according to claim 12, wherein
the first film and the second film have different internal stresses.

14. The manufacturing method according to claim 12, wherein
the first film and the second film have different densities.

15. The manufacturing method according to claim 12, wherein
the first film contains carbon or nitrogen at a first concentration, and
the second film contains carbon or nitrogen at a second concentration different from the first concentration.
